(19) United States
(12) Patent Application Publication
(10) Pub. No.: US 2009/0123877 A1
(43) Pub. Date: May 14, 2009

(54) METHOD FOR FORMING AN OPENING OF NANO-METER SCALE

(76) Inventors: Hui-Shen Shih, Chang-Hua Hsien (TW); Yu-Fang Chien, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/940,305

(22) Filed: Nov. 14, 2007

(51) Int. Cl. B28B 11/08; G03F 7/00

(52) U.S. Cl. 430/322; 264/293

(57) ABSTRACT

A method for forming an opening of nano-meter scale includes providing a substrate with a material layer, and later forming a first part of the opening and then forming a second part of the opening in the material layer. At least one of the first part and the second part of the opening is formed by imprint.

### BACKGROUND OF THE INVENTION

1. Field of the Invention

The present invention relates to a method for forming an opening of nano-meter scale. More particularly, the present invention relates to a method for forming an opening of nano-meter scale by selective imprint.

2. Description of the Prior Art

The metal wires in the multilevel interconnection in the traditional integrated circuits are usually formed by the dry etching of the metal layers, then the dielectric gaps are filled as the insulation. However, when aluminum must be replaced by a much better conductor, copper, to overcome the technical problems, copper must be deposited on the dielectric layers with pre-determined trenches and vias due to less effectiveness of traditional etching on copper. This is called “damascene.”

As mentioned above, the damascene technique is essential to the copper process of pursuing much lower resistance because the damascene technique first defines the patterns for the metal wires on the dielectric layer then to fill the gaps with metal so that the direct etching of the metal may be omitted. In addition, based on the etching fashions of the dielectric layer, the damascene technique may be classified into various types such as “trench first” or “via first,” each with its different technical problems.

US patent application 2006/0261518 provides a use of step and flash imprint lithography for direct imprinting of dielectric materials for dual damascene processing. After a dielectric precursor liquid on a substrate is directly imprinted by a multi-layer template, it is then cured by light. After the template is released, the dielectric layer is again thermally cured to form a dielectric structure including trench pattern and via pattern. Because trenches and vias each have different criteria for formation and dimension, a single imprint step has difficulty in meeting all of the demands. Furthermore, a single imprint step may apply an overly great stress on the underlying layers.

Accordingly, a novel selective imprint method is needed to form an opening of nano-meter scale, which is capable of meeting all the demands for trenches and vias and not applying an overly great stress on the underlying layers.

### SUMMARY OF THE INVENTION

The present invention provides a novel method for form an opening of nano-meter scale, preferably for damascene technique. The selective imprint is used to meet different demands of forming trenches and vias but not to apply an overly great stress on the underlying layers.

The method for forming an opening of nano-meter scale of the present invention includes first providing a substrate with a material layer. Later a first part of the opening and then a second part of the opening is independently formed in the material layer. At least one of the first part and the second part of the opening is formed by imprint. The first part may be larger or smaller than the second part. The first part may also be as large as the second part.

Because the method of the present invention employs the selective imprinting procedure to form at least one of the first opening and the second opening to meet the different demands of forming trenches and vias, it does not apply an overly great stress on the underlying layers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate the “via first” method for forming an opening of nano-meter scale of the present invention.

FIGS. 9-13 illustrate the “trench first” method for forming an opening of nano-meter scale of the present invention.

FIGS. 14-17 illustrate the method for forming an opening of nano-meter scale of the present invention applied in the single damascene field.

FIGS. 18-23 illustrate the “dual damascene of single layer” method of the present invention.

### DETAILED DESCRIPTION

The present invention provides a novel method for forming an opening of nano-meter scale, preferably for damascene technique. The selective imprinting procedure is capable of meeting the different demands of forming trenches and vias. Moreover, the imprint procedure may be performed stepwisely to achieve a soft landing so as to apply the stress damage as less as possible to the underlying layers.

Traditionally the damascene technique may be “single damascene” or “dual damascene.” Additionally, the dual damascene may have variations such as “trench first” or “via first.” The followings are some preferred embodiments of the method of the present invention.

Via First

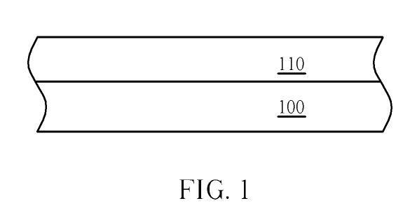

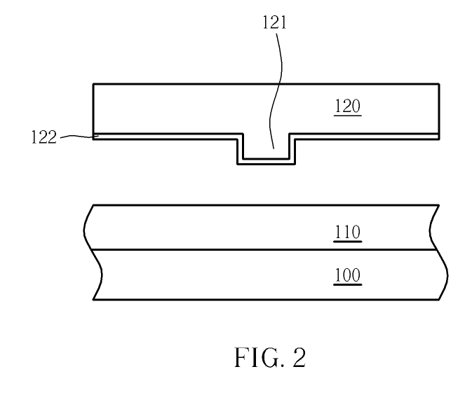

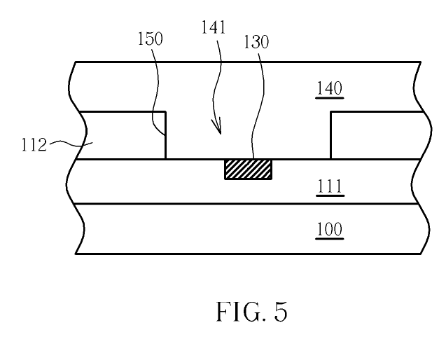

FIGS. 1-8 illustrate the “via first” method for forming an opening of nano-meter scale of the present invention. If vias are required to be formed in the first place, firstly a substrate 100 in provided, as shown in FIG. 1, in the method of the present invention. The substrate 100 may be, for example, wafers or SOI with manufactured MOSs thereon. Later a material layer 110 is formed on the substrate 1 00. Besides, as shown in FIG. 2, a template 120 with desired nano-scale imprint patterns 121 is provided. The template 120 may be transparent such as quartz to facilitate the photo-curing or a thermo-conductive material to facilitate the thermo-curing. The imprint patterns 121 on the template 120 is the needed patterns. The material layer 110 may be a single layer structure or a multi-layer structure. If the material layer 110 is a multi-layer structure, the multi-layer structure may have dielectric layers constructed in order, such as a first dielectric layer 111/second dielectric structure 112 (FIG. 5), and include low-k materials to form a dual damascene structure.

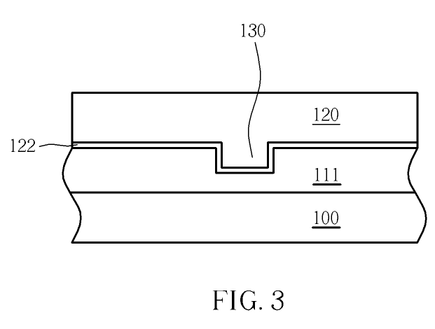

Take the material layer 110 of multi-layer for example, after the first dielectric layer 111 is formed on the surface of the substrate 100, later as shown in FIG. 3, the imprint patterns 121 on the template 120 are then transferred to the first dielectric layer 111 by way of imprint to from the via 130. In order to facilitate the transfer of the imprint patterns 121 onto the first dielectric layer 111, the material layer 110 is preferably plastic, such as gel-type material, foam-type material, spin-on dielectric material or the combination thereof, to be cured after a proper curing procedure. For example, the template 120 may have a cooling or heating device to assist the curing procedure.

In order to diminish the interaction between the template 120 and the first dielectric layer 111 to facilitate the release of the template 120 after the imprint patterns 121 being formed, there may be an optional release layer 122 on the template 120. The release layer 122 may include a material of low surface energy, such as poly-tetrafluroethyelen (PTFE) or octadecyl trichlorosilane (OTS). The release layer 122 may possibly simultaneously transfer onto the first dielectric layer 111 after the template 120 is released because the release layer 122 has low surface energy.

Besides, because copper is frequently used in the damascene technique, the release layer 122 may preferably serve as a barrier layer of copper to avoid undesirable diffusing to the dielectric layer. On the other hand, if W, Ti, TiN are used in the damascene technique, the release layer 122 may preferably serve as a glue layer to enhance the affinity between the filling material and the material layer 110. Furthermore, the release layer 1 22 may also serve as a seed layer to assist the following deposition of the material.

Afterwards, optionally, the first dielectric layer 111 may be cured. The first dielectric layer 111 may be cured by way of in situ/ex situ or by light/thermally. In situ curing means that the first dielectric layer 111 is cured before the template 120 is released. Ex situ curing means that the first dielectric layer 111 is cured only after the template 120 is released. Besides, the curing of the first dielectric layer 111 may be enhanced by way of light or by heat depending on the intrinsic feature of the material.

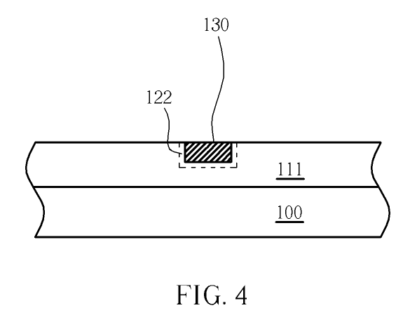

Then, as shown in FIG. 4, the via 130 may be filled with conductive materials. As mentioned before, the conductive materials may be Cu, W, Ti, or TiN . . . etc. The first conductive material may fill the via 130 in a manner of traditional methods. Optionally, CMP may be later employed to make the conductive material just fill the via 130.

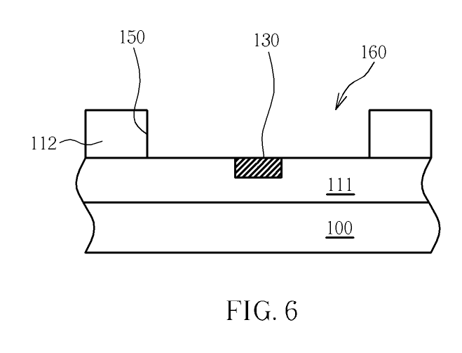

To be continued, as shown in FIG. 5, the previous steps may be optionally repeated to transfer another trench pattern 141 defining the trenches on the mold 140 to a second dielectric structure 112 to form the trench 150. The opening 160 now is completed. As shown in FIG. 6, the mold 140 may be transparent such as quartz to facilitate the photo-curing or a thermo-conductive material to facilitate the thermo-curing. The opening 160 may include two parts, i.e. the first part being the via 130 and the second part being the trench 150. The second dielectric structure 112 may be cured by a curing process.

In order to facilitate the transfer of the trench pattern 141 onto the second dielectric structure 112, the second dielectric structure 112 is preferably plastic, such as gel-type material, foam-type material, or the combination thereof, to be cured after a proper curing procedure.

In order to diminish the interaction between the mold 140 and the second dielectric structure 112 to facilitate the release of the mold 140 after the trench pattern 141 being formed, there may be an optional release layer on the mold 140. The release layer may include a material of low surface energy, such as poly-tetrafluroethyelen (PTFE) or octadecyl trichlorosilane (OTS). The release layer may possibly simultaneously transfer onto the second dielectric structure 112 after the mold 140 is released because the release layer has low surface energy.

Besides, because copper is frequently used in the damascene technique, the release layer may preferably serve as a barrier layer of copper to avoid undesirable diffusing to the dielectric layer. On the other hand, if W, Ti, TiN are used in the damascene technique, the release layer may preferably serve as a glue layer to enhance the affinity between the filling material and the second dielectric structure 112. Furthermore, the release layer may also serve as a seed layer to assist the deposition of the material.

Afterwards, optionally, the second dielectric structure 112 may be cured. The second dielectric structure 112 may be cured by way of in situ/ex situ or by light/thermally. In situ curing means that the second dielectric structure 112 is cured before the mold 140 is released. Ex situ curing means that the second dielectric structure 112 is cured only after the mold 140 is released. Besides, the curing of the second dielectric structure 112 may be enhanced by way of light or by heat depending on the intrinsic feature of the material.

Then the opening 160 may be filled with conductive materials (not shown), or optionally, CMP may be employed.

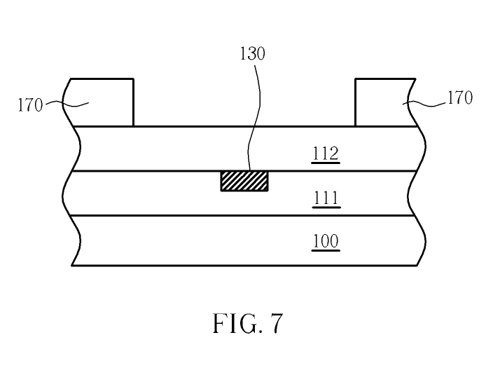

On the other hand, the second part, i.e. the trench 150, of the opening 160 may be formed by etching. After the first conductive material fills the via 130, as shown in FIG. 6, a second dielectric structure 112 will be formed by the definition of the photoresist 170 of the trench pattern, as shown in FIG. 7.

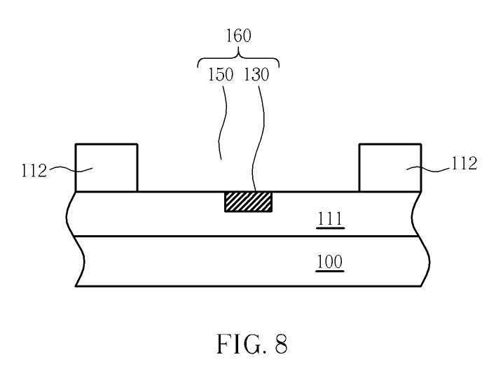

To be continued, the exposed second dielectric structure 112 is removed by etching procedure, such as dry etching, to form the trench 150. The opening 160 now is completed, as shown in FIG. 8. The opening 160 may include two parts, i.e. the first part being the via 130 and the second part being the trench 150. No matter how the opening 160 is formed, it may be further optionally trimmed. For example, the first par and/or the second part may be trimmed by lithography. Later, the opening is filled with a second conductive material. Optionally, CMP may be employed.

Trench First

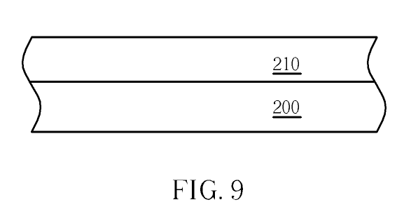

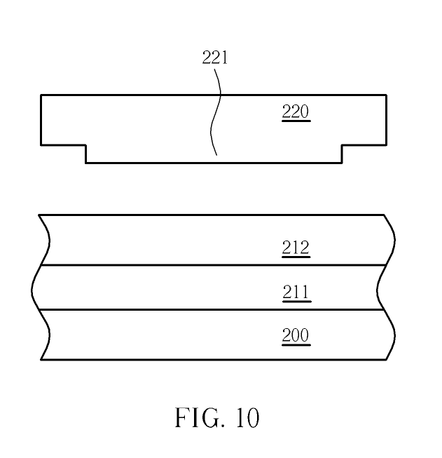

FIGS. 9-13 illustrate the “trench first” method for forming an opening of nano-meter scale of the present invention. If trenches are required to be formed in the first place, firstly a substrate 200 in provided, as shown in FIG. 9, in the method of the present invention. The substrate 200 may be, for example, wafers or SOI with manufactured MOSs thereon. Later a material layer 210 is formed on the substrate 200. Besides, as shown in FIG. 10, a mold 220 with desired nano-scale imprint patterns 221 is provided. The mold 220 may be transparent such as quartz to facilitate the photo-curing or a thermo-conductive material to facilitate the thermo-curing. The imprint patterns 221 on the mold 220 are the needed patterns. The material layer 210 may be a single layer structure or a multi-layer structure. If the material layer 210 is a multi-layer structure, the multi-layer structure may be dielectric layers constructed in order, such as a first dielectric layer 211/second dielectric structure 212, and include low-k materials to form a dual damascene structure.

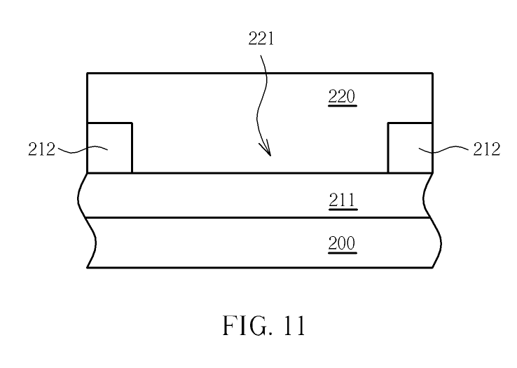

As shown in FIG. 11, the trench pattern 221 on the mold 220 is then transferred to the second dielectric layer 212 by way of imprint. In order to facilitate the transfer of the trench pattern 221 onto the second dielectric layer 212, the first dielectric layer 211 is preferably solid and the second dielectric layer 212 is preferably plastic, such as gel-type material, foam-type material, solid-type material precursor or the combination thereof, to be cured after a proper curing procedure. For example, the mold 220 may have a cooling or heating device to assist the curing procedure.

In order to diminish the interaction between the mold 220 and the second dielectric layer 212 to facilitate the release of the mold 220 after the trench pattern 221 being formed, there may be an optional release layer on the mold 220. The release layer may include a material of low surface energy, such as poly-tetrafluroethyelen (PTFE) or octadecyl trichloro silane (OTS). The release layer may possibly simultaneously transfer onto the second dielectric layer 212 after the mold 220 is released because the release layer has low surface energy.

Besides, because copper is frequently used in damascene technique, the release layer may preferably serve as a barrier layer of copper to avoid undesirable diffusing to the dielectric layer. On the other hand, if W, Ti, TiN are used in damascene technique, the release layer may preferably serve as a glue layer to enhance the affinity between the filling material and the second dielectric layer 212. Furthermore, the release layer may also serve as a seed layer to assist the deposition of the material.

Afterwards, optionally, the second dielectric layer 212 may be cured. The second dielectric layer 212 may be cured by way of in situ/ex situ or by light/thermally. In situ curing means that the second dielectric layer 212 is cured before the mold 220 is released. Ex situ curing means that second dielectric layer 212 is cured only after the mold 220 is released. Besides, the curing of the second dielectric layer 212 may be enhanced by way of light or by heat depending on the intrinsic feature of the material.

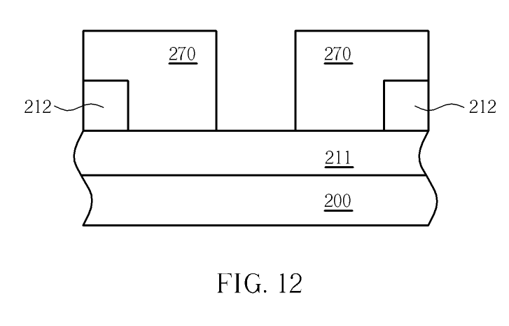

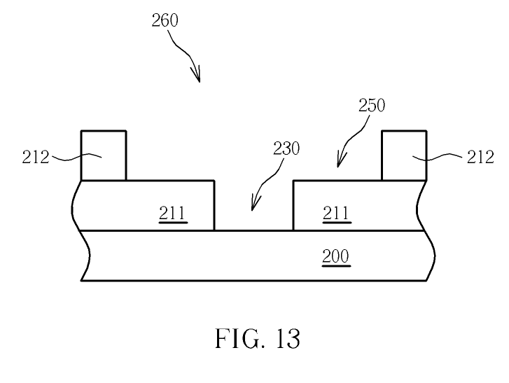

Then, as shown in FIG. 12, the second part of the opening 260, i.e. the via 230 may be defined by etching. After the trench 250 is formed, the via 230 may be defined by a photoresist 270 (FIG. 13).

To be continued, the exposed first dielectric structure 211 is removed by etching procedure, such as dry etching, to form the via 230. The opening 260 now is completed after the photoresist 270 is removed, as shown in FIG. 13. The opening 260 may include two parts, i.e. the first part being the trench 250 and the second part being the via 230. No matter how the opening 260 is formed, it may be further optionally trimmed. For example, the first par and/or the second part may be trimmed by lithography. Later, the opening 260 is filled with the conductive material. Optionally, CMP may be employed.

Single Damascene

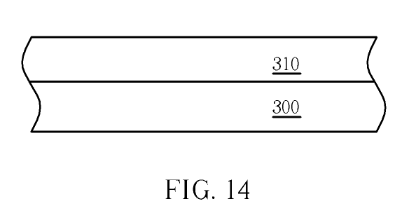

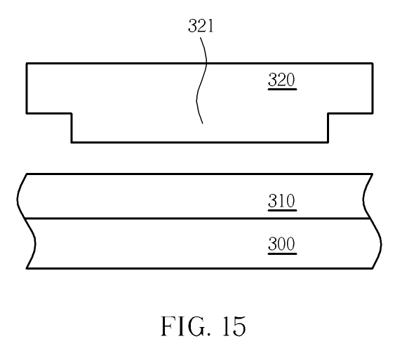

The method for forming an opening of nano-meter scale may also be applied in the single damascene field. FIGS. 14-17 illustrate the method for forming an opening of nano-meter scale of the present invention is applied in the single damascene field. A substrate 300 is first provided, as shown in FIG. 14. The substrate 300 may be, for example, wafers or SOI with manufactured MOSs thereon. Later a material layer 310 is formed on the substrate 300. Besides, as shown in FIG. 15, a mold 320 with desired nano-scale imprint patterns 321 is provided. The mold 320 may be transparent such as quartz to facilitate the photo-curing or a thermo-conductive material to facilitate the thermo-curing. The imprint patterns 321 on the mold 320 is the needed patterns. The material layer 310 may be a single layer structure or a multi-layer structure and preferably includes low-k materials.

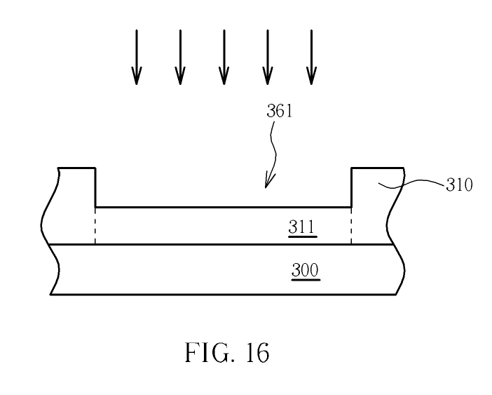

As shown in FIG. 16, the single damascene pattern 321 on the mold 320 is then transferred to the material layer 310 by way of imprint. In order to facilitate the transfer of the single damascene pattern 321, such as a trench pattern, onto the material layer 310, the material layer 310 is preferably plastic, such as gel-type material, foam-type material, solid-type material precursor or the combination thereof, to be cured after a proper curing procedure. For example, the mold 320 may have a cooling or heating device to assist the curing procedure.

To be noticed, if the opening 360 is completed only by a single imprint procedure, the underlying layers may potentially suffer too much stress by the direct contact of the mold 320. Accordingly, in this step the mold 320 does not directly contact the substrate 300 so that a pattern 361 and a buffer region 311 are formed.

In order to diminish the interaction between the mold 320 and the material layer 310 to facilitate the release of the mold 320 after the single damascene pattern 321 being formed, there may be an optional release layer on the mold 320. The release layer may include a material of low surface energy, such as poly-tetrafluroethyelen (PTFE) or octadecyl trichloro silane (OTS). The release layer may possibly simultaneously transfer onto the material layer 310 after the mold 320 is released because the release layer has low surface energy.

Besides, because copper is frequently used in the damascene technique, the release layer may preferably serve as a barrier layer of copper to avoid undesirable diffusing to the dielectric layer. On the other hand, if W, Ti, TiN are used in the damascene technique, the release layer may preferably serve as a glue layer to enhance the affinity between the filling material and the material layer 310. Furthermore, the release layer may also serve as a seed layer to assist the deposition of the material.

Afterwards, optionally, the material layer 310 may be cured. The material layer 310 may be cured by way of in situ/ex situ or by light/thermally. In situ curing means that the material layer 310 is cured before the mold 320 is released. Ex situ curing means that the material layer 310 is cured only after the mold 320 is released. Besides, the curing of the material layer 310 may be enhanced by way of light or by heat depending on the intrinsic feature of the material.

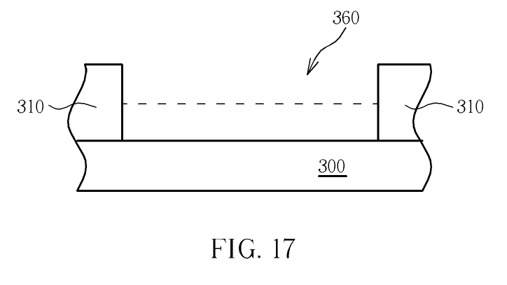

Then, the buffer region 311 may be removed by etching. The material layer 310 may be used as an etching mask to perform the etching procedure till the substrate 300 is exposed. As shown in FIG. 17, the opening 360 now is completed and includes two parts, i.e. the first part being the pattern 361 and the second part being the buffer region 311. No matter how the opening 360 is formed, it may be further optionally trimmed. For example, the opening 360 may be trimmed by lithography. Later, the opening 360 is filled with the conductive material. Optionally, CMP may be employed.

Dual Damascene Of Single Layer

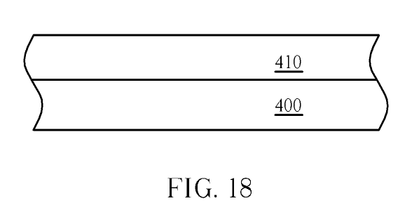

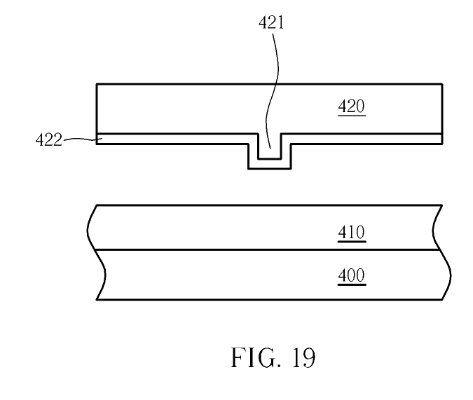

The method for forming an opening of nano-meter scale may also be applied in the dual damascene of single layer. FIGS. 18-23 illustrate the “dual damascene of single layer” method of the present invention. First a substrate 400 is provided, as shown in FIG. 18. The substrate 400 may be, for example, wafers or SOI with manufactured MOSs thereon. Later a material layer 410 is formed on the substrate 400. Besides, as shown in FIG. 19, a mold 420 with desired nano-scale imprint patterns 421 is provided. The mold 420 may be transparent such as quartz to facilitate the photo-curing or a thermo-conductive material to facilitate the thermo-curing. The imprint patterns 421 on the mold 420 is the needed patterns. The material layer 210 may be a single layer structure, such as a dielectric layer, and includes low-k materials to form a dual damascene structure.

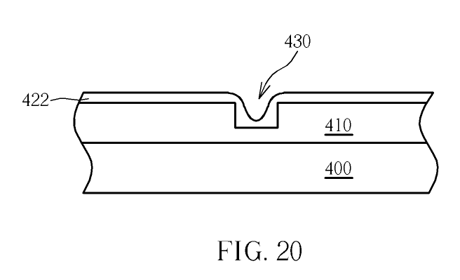

As shown in FIG. 20, the via pattern 421 on the mold 420 is then transferred to the material layer 410 by way of imprint to form the via 430. In order to facilitate the transfer of the via pattern 421 on the mold 420 onto the material layer 410, the material layer 410 is preferably plastic, such as gel-type material, foam-type material, solid-type material precursor or the combination thereof, and the coated flowing material layer may be cured after a proper curing procedure. Further, the mold 420 may additionally have recess(es) (not shown) to accommodate the excess flowing material layer. To facilitate the formation of the material layer, the mold 420 may have a cooling or heating device to assist the curing procedure.

In order to diminish the interaction between the mold 420 and the material layer 410 to facilitate the release of the mold 420 after the via pattern 421 being formed, there may be an optional release layer 422 on the mold 420. The release layer 422 may include a material of low surface energy, such as poly-tetrafluroethyelen (PTFE) or octadecyl trichloro silane (OTS). The release layer 422 may possibly simultaneously transfer onto the material layer 410 after the mold 420 is released because the release layer 422 has low surface energy.

Optionally, the material layer 410 may be cured. The material layer 410 may be cured by way of in situ/ex situ or by light/thermally. In situ curing means that the material layer 410 is cured before the mold 420 is released. Ex situ curing means that material layer 410 is cured only after the mold 420 is released. Besides, the curing of the material layer 410 may be enhanced by way of light, such as UV light, or by heat depending on the intrinsic feature of the material.

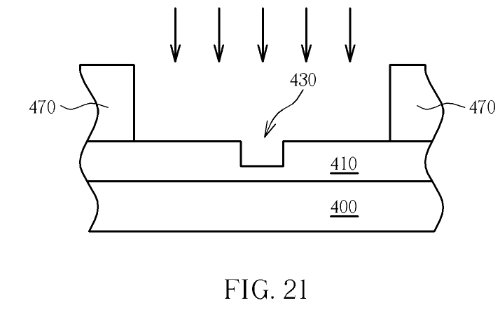

The second part of the dual damascene opening, i.e. the trench 450 may be defined by etching. The trench pattern in the dual damascene opening may be defined by a photoresist 470, as shown in FIG. 21.

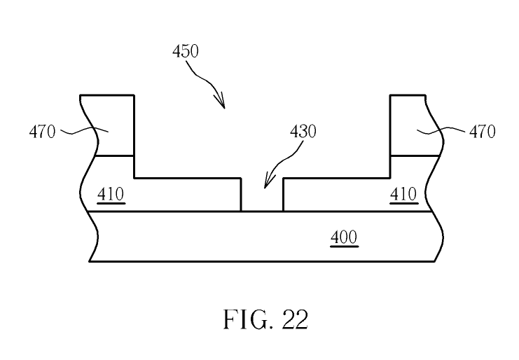

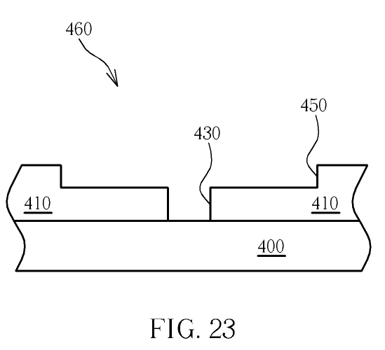

To be continued, the exposed material layer 410 is anisotropically removed by etching procedure downwards, such as dry etching, to form the trench 450, as shown in FIG. 22, and the via 230 extends downwards to the surface of the substrate 400, as shown in FIG. 23. The opening 260 now is completed and includes two parts, i.e. the first part being the extending via 430 and the second part being the trench 450. Similarly, no matter how the opening 460 is formed, it may be further optionally trimmed. For example, the first par and/or the second part may be trimmed by lithography. Later, the opening 460 is filled with the conductive material. Optionally, CMP may be employed.

On the other hand, if the pre-determined patterns on the substrate include repeated patterns and non-repeated patterns, the method for forming an opening of nano-meter scale of the present invention may be suitable in forming the repeated patterns. It is simple, convenient, fast and of low-cost.

In view of the above, the method for forming an opening of nano-meter scale of the present invention may be used in forming repeated patterns or non-repeated patterns of various single damascene and dual damascene techniques as well as in single-layer or multi-layer dielectric structures. The selective imprint is useful to meet the different criteria of forming trenches and vias. Additionally, if the selective imprint is performed stepwisely, it may achieve a soft landing so as to apply the stress damage as less as possible to the underlying layers.

Those skilled in the art will readily observe that numerous modifications and alterations of the device and method may be made while retaining the teachings of the invention.

What is claimed is:

1. A method for forming an opening of nano-meter scale, comprising:
providing a substrate with a material layer; and
forming a first part of said opening then forming a second part of said opening in said material layer, wherein at least one of said first part and said second part of said opening is formed by using a template to imprint.

2. The method of claim 1, wherein said first part of said opening is larger than said second part of said opening.

3. The method of claim 1, wherein said first part of said opening is smaller than said second part of said opening.

4. The method of claim 1, wherein said first part of said opening is as large as said second part of said opening.

5. The method of claim 1, wherein said first part and said second part of said opening is independently formed by at least two imprints.

6. The method of claim 1, wherein said first part of said opening is formed by at least one imprint and said second part of said opening is formed by at least one lithography.

7. The method of claim 1, wherein said first part of said opening is formed by at least one etching and said second part of said opening is formed by at least one imprint.

8. The method of claim 1, wherein said template comprises a release layer.

9. The method of claim 8, wherein said release layer is a barrier layer.

10. The method of claim 8, wherein said release layer is a glue layer.

11. The method of claim 8, wherein said release layer is a seed layer.

12. The method of claim 8, wherein said release layer comprises a material of low surface energy.

13. The method of claim 8, wherein said release layer is selected from a group consisting of PTFE and OTS.

14. The method of claim 1, wherein said first part of said opening is formed in a first dielectric layer of said material layer.

15. The method of claim 14, wherein said first dielectric layer is selected from a group consisting of a gel-type material, a foam-type material and a spin-on dielectric material when said first part is formed by imprint.

16. The method of claim 14, wherein said first part is formed by lithography.

17. The method of claim 14, wherein said second part of said opening is formed in a second dielectric layer of said material layer.

18. The method of claim 17, wherein said first dielectric layer and said second dielectric layer are the same.

19. The method of claim 17, wherein said first dielectric layer and said second dielectric layer are different.

20. The method of claim 17, wherein said second dielectric layer is selected from a group consisting of a gel-type material, a foam-type material and a spin-on dielectric material when said second part is formed by imprint.
